(19) United States
(12) Patent Application Publication
(10) Pub. No.: US 2026/0205129 A1
(43) Pub. Date: Jul. 16, 2026

(54) FAST-SETTLING THRESHOLD ESTIMATOR FOR A BIT SLICER

(71) Applicant: NXP USA, Inc., AUSTIN, TX (US)

(72) Inventors: Gerben Willem de Jong, VELDHOVEN (NL); Hans Peter Stoorvogel, Heumen (NL); Tino Copani, Riposto (IT); Olivier Crand, Parfouru sur Odon (FR)

(21) Appl. No.: 19/448,768

(22) Filed: Jan. 14, 2026

(30) Foreign Application Priority Data
Jan. 14, 2025 (EP) 25305037.1

(51) Int. Cl. H03M 1/06

(52) U.S. Cl. CPC H03M 1/0658

(57) ABSTRACT

An electronic circuit includes a fast-settling threshold estimator for determining a fast-settling threshold voltage which includes a maximum peak detector that receives an analog signal containing digital data and produces an estimate of a maximum value of the analog signal; a differentiator that produces an output voltage responsive to a change in the estimate of a maximum value of the analog signal; a preselected voltage coupled to a comparator that outputs a pulse when the output voltage is greater than the preselected voltage; a minimum peak detector that produces an estimate of a minimum value of the analog signal; and an averaging circuit that produces a weighted average of the estimate of a maximum value of the analog signal and the estimate of a minimum value of the analog signal. In one embodiment, the fast-settling threshold estimator is coupled to a bit slicer and to a RF receiver.

### BACKGROUND

This application claims the priority under 35 U.S.C. § 119 of European Patent application no. 25305037.1 filed on 14 Jan. 2025, the contents of which are incorporated by reference herein.

### FIELD

This invention relates generally to electronic circuits, and more specifically to a threshold estimator for a bit slicer.

### RELATED ART

A wireless receiver that receives a radio frequency analog signal representing digital data typically includes a demodulator that converts a frequency of the analog signal to a baseband frequency and outputs a demodulated signal to a bit slicer. The demodulated signal may represent a combination of an amplitude of the analog signal, noise, interference from other received signals, and distortion caused by circuitry of the wireless receiver. The bit slicer detects a binary signal within the demodulated signal by continually comparing a voltage of the demodulated signal with a threshold voltage. If the voltage of the demodulated signal is higher than the threshold voltage, then an output of the bit slicer goes high which is usually interpreted to represent a digital “1”. If the voltage of the demodulated signal is lower than the threshold voltage, then the output of the bit slicer goes low which is usually interpreted to represent a digital “0”. The bit slicer may be coupled to a threshold estimator that estimates a value of the threshold voltage based, at least in part, on characteristics of the demodulated signal.

### SUMMARY

Aspects of the present disclosure are defined in the accompanying claims.

### BRIEF DESCRIPTION OF THE DRAWINGS

The present invention is illustrated by way of example and is not limited by the accompanying figures, in which like references indicate similar elements.

FIG. 1 is a simplified functional block diagram of a radio frequency (RF) receiver coupled to a fast-settling threshold estimator and to a bit slicer.

FIG. 2 is a simplified functional block diagram of the fast-settling threshold estimator of FIG. 1 in accordance with one embodiment of the invention, coupled to the bit slicer.

FIG. 3 is a simplified functional block diagram of a maximum peak detector, in accordance with one embodiment of the invention.

FIG. 4 is a simplified functional block diagram of a minimum peak detector, in accordance with one embodiment of the invention.

FIG. 5 is a simplified functional block diagram of a first example of an integrator in accordance with one embodiment of the invention.

FIG. 6 is a simplified functional block diagram of a second example of an integrator in accordance with one embodiment of the invention.

FIG. 7 is a graph of signals present in a simulation of the fast-settling threshold estimator shown in FIG. 2.

FIG. 8 is another graph of signals present in a simulation of the fast-settling threshold estimator shown in FIG. 2.

FIG. 9 is a simplified functional block diagram of a minimum peak detector with a simplified reset circuit, in accordance with one embodiment of the invention.

### DETAILED DESCRIPTION

A fast-settling threshold estimator in accordance with the invention receives an analog signal and outputs a threshold voltage to a bit slicer that also receives the analog signal. The threshold voltage advantageously settles very fast, i.e., it has a high attack, at a beginning of a data packet (hereinafter “packet”) and the threshold voltage is advantageously very stable during the packet. The fast-settling threshold estimator includes a differentiator that detects a sudden change in voltage of an output signal of a maximum peak detector. The fast-settling threshold estimator initializes a minimum peak detector at a beginning of every packet which is typically when the sudden change in voltage of the output signal of the maximum peak detector occurs. A bit slicer contributes to reconstruction of original bits in the analog signal by comparing a voltage of the analog signal with a threshold voltage.

To obtain a fast-settling of a threshold estimation, both the maximum peak detector and the minimum peak detector should settle quickly at the beginning of each packet. Fast-settling of the threshold estimation requires a temporarily fast decay of an output of the minimum peak detector. A fast decay requires a large decay current. Advantageously, the minimum peak detector in accordance with the invention has a temporarily large decay current. A peak detector should also produce an output signal that is flat versus time. A flat threshold level versus time requires a slow decay. Advantageously, both peak detectors in the fast-settling threshold estimator in accordance with the invention have a small decay current during most of each packet.

At the beginning of a packet, the maximum peak detector is in attack mode; therefore, the maximum peak detector is fast. At the beginning of a packet, the minimum peak detector is in decay mode. Known minimum peak detectors disadvantageously decay slowly at the beginning of a packet. However, the fast-settling threshold estimator in accordance with the invention overcomes this deficiency by “initializing” the minimum peak detector, which means that a decay speed of the minimum peak detector is temporarily increased. Only temporarily, because a permanent increase of the decay speed would result in a non-flat threshold level versus time. With initialization of the minimum peak detector, the output voltage of the minimum peak detector quickly settles to a current value of the analog signal. The quick settling is done by temporarily increasing the decay speed of the minimum peak detector. Consequently, the minimum peak detector in accordance with the invention advantageously balances a fast-settling of the threshold estimation with a flat threshold level versus time.

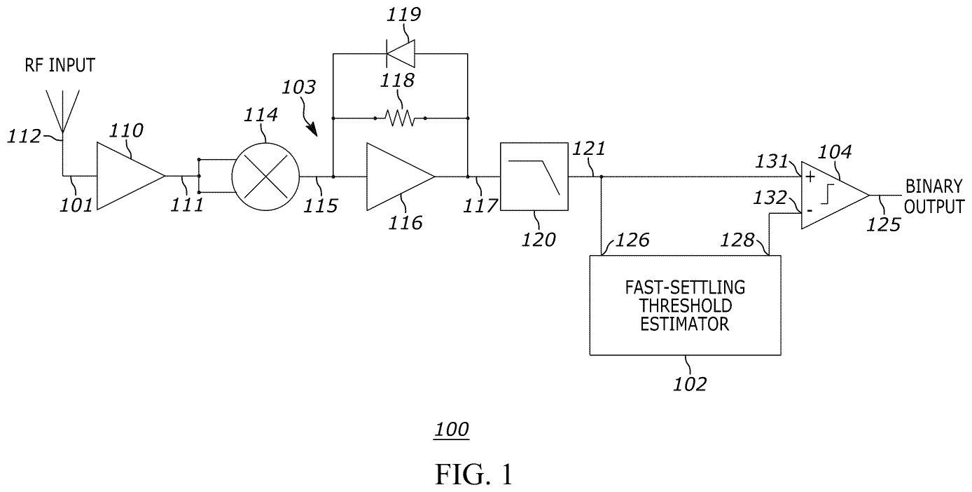

FIG. 1 is a simplified functional block diagram of electronic circuits 100 comprising a radio frequency (hereinafter “RF”) receiver 103 coupled to a fast-settling threshold estimator 102 and to a bit slicer 104. The RF receiver 103 may receive an RF analog signal 101 representing digital data. The RF receiver 103 includes an RF low-noise amplifier 110 coupled to an antenna 112 for receiving the RF analog signal 101, and for outputting an amplified RF analog signal 111. In one embodiment, the RF signal is a 60.5-GHz on/off-keying-modulated (OOK) RF carrier with a minimum on-level of −42 dBm. The RF low-noise amplifier 110 is coupled to an RF-envelope detector 114, which is a self-mixer. The RF-envelope detector 114 downmixes the amplified RF analog signal 111 to a baseband analog signal 115. The RF-envelope detector 114 is coupled to a baseband transimpedance amplifier (hereinafter “TIA”) 116 that outputs an amplified baseband analog signal 117. In the illustrated embodiment, a feedback resistor 118 is coupled between an input terminal and an output terminal of the baseband TIA 116. In the illustrated embodiment, the RF-envelope detector 114 is a quadratic envelope detector. In another embodiment, the RF-envelope detector 114 is an absolute-law envelope detector. In yet another embodiment, a semi-logarithmic RF-envelope detector is included within a semi-logarithmic baseband TIA 116 in which case a diode 119 is coupled between the input terminal and the output terminal of the baseband TIA 116 in parallel with the feedback resistor 118. Although diode 119 is used with the illustrated implementation of the semi-logarithmic baseband TIA 116; an actual implementation of the semi-logarithmic TIA would be more complicated. A semi-logarithmic transfer offers an instantaneous reduction of dynamic range, without introducing any settling issues. Therefore, the use of a semi-logarithmic transfer is advantageous, given the large dynamic range of the RF analog signal 101, combined with the requirement for fast settling.

The TIA 116 is coupled to a baseband low-pass filter 120. In one embodiment, the baseband low-pass filter 120 is a 300 MHz second-order Butterworth filter. The baseband low-pass filter 120 outputs a filtered amplified baseband analog signal (hereinafter “analog signal”) 121 to an input terminal 126 of the fast-settling threshold estimator 102 and to a first input terminal 131 of the bit slicer 104. In one embodiment, the analog signal 121 has a voltage between 0V and 1V. An output terminal 128 of the fast-settling threshold estimator 102 is coupled to a second input terminal 132 of the bit slicer 104. In the illustrated embodiment, the bit slicer 104 consists of a bit-slicing voltage comparator having a positive input terminal and a negative input terminal. In one embodiment, a binary output 125 of the bit slicer 104 has a rate of 600 Mb per second. The fast-settling threshold estimator 102 and the bit slicer 104 receive a packet of digital data embedded in the analog signal 121. The packet of digital data usually lacks a well-defined high level and a well-defined low level. Therefore, the fast-settling threshold estimator 102 which determines a slicing level of the digital data in the analog signal 121 is needed.

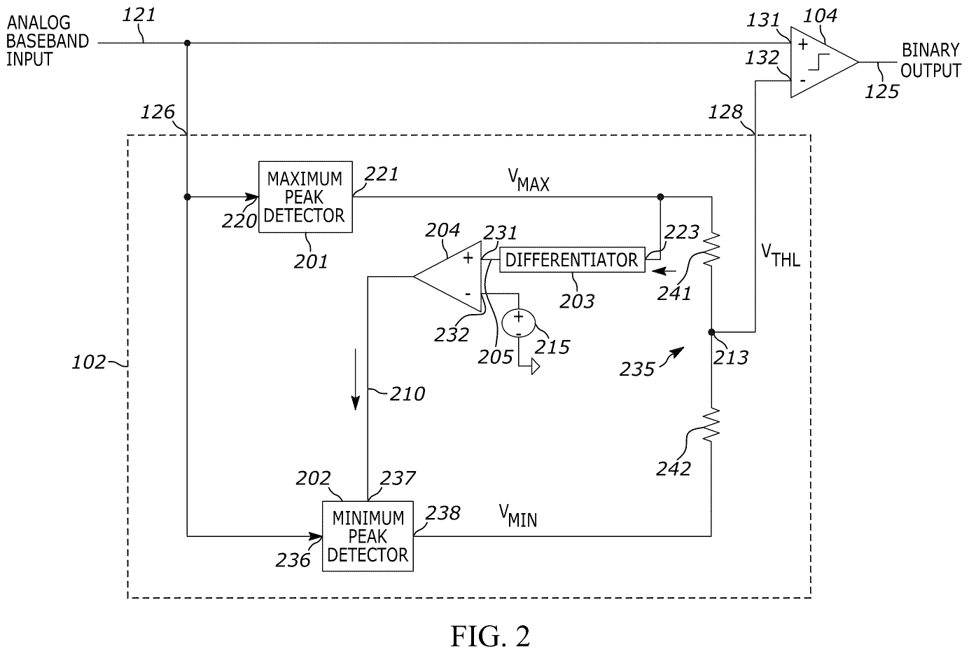

FIG. 2 is a simplified functional block diagram of the fast-settling threshold estimator 102. The fast-settling threshold estimator 102 outputs a fast-settling threshold voltage (V_{THL}) that serves as the slicing level of the digital data conveyed by the analog signal 121. The binary output 125 of the bit slicer 104 is based on the digital data embedded in the analog signal 121 and on V_{THL}.

The fast-settling threshold estimator 102 includes the input terminal 126 for receiving the analog signal 121, the output terminal 128 coupled to the bit slicer 104, a maximum peak detector 201, a minimum peak detector 202, a differentiator 203, a voltage comparator (hereinafter “comparator”) 204 and an averaging circuit 235. The maximum peak detector 201 has an input terminal 220 and an output terminal 221. The maximum peak detector 201 outputs a V_{MAX} signal which corresponds to a maximum value of the analog signal 121. The minimum peak detector 202 has a first input terminal 236, a reset input terminal 237 and an output terminal 238. The minimum peak detector 202 outputs a V_{MIN} signal which corresponds to a minimum value of the analog signal 121. In the illustrated embodiment, the averaging circuit 235 includes a first resistor 241 having one end coupled to the output terminal 221 of the maximum peak detector 201 and another end coupled to a node 213, and a second resistor 242 having one end coupled to the output terminal 238 of the minimum peak detector 202 and another end coupled to the node 213. An output of the averaging circuit 235 is a weighted average of the output voltage of the maximum peak detector 201 and the output voltage of the minimum peak detector 202. The output of the averaging circuit 235 is the fast-settling threshold voltage V_{THL}. The fast-settling threshold voltage V_{THL} is characterized both by attack speed and decay speed of the maximum peak detector 201 and by attack speed and decay speed of the minimum peak detector 202.

Known threshold estimators use resistors of equal resistance in their averaging circuit. If the first resistor 241 and the second resistor 242 have equal resistances, then V_{THL}=(V_{MAX}+V_{MIN})/2. However, in some embodiments of the fast-settling threshold estimator 102 the first resistor 241 and the second resistor 242 advantageously have unequal resistances. Optimum values of the first resistor 241 and the second resistor 242 depend upon a type of envelope detector coupled to the fast-settling threshold estimator 102. Examples of the type of envelope detector are: absolute-law, quadratic and semi-logarithmic. For the absolute-law envelope detector, first resistor 241 and second resistor 242 are approximately equal. For the quadratic envelope detector, first resistor 241 is larger than second resistor 242. For the semi-logarithmic envelope detector, second resistor 242 is larger than first resistor 241. The values of first resistor 241 and second resistor 242 also depend, in part, on a signal-to-noise ratio of the RF analog signal 101. The output of the fast-settling threshold estimator 102 is the threshold voltage (V_{THL}) at node 213. The fast-settling threshold estimator 102 outputs an optimum slicing level for a particular envelope detector. The optimum slicing level is selected to correspond to a voltage at which the probability density of a high level (a digital “1”) plus Gaussian noise equals the probability density of a low level (a digital “0”) plus Gaussian noise. The optimum slicing level is determined, in part, by the resistances of the first resistor 241 and the second resistor 242. The slicing level/threshold is estimated using the maximum peak detector 201 and the minimum peak detector 202 together with the first resistor 241 and the second resistor 242 to obtain a weighted average of a maximum value and a minimum value of the analog signal 121. The weighted average is controlled by the resistances of the first resistor 241 and the second resistor 242. In this way, the bit slicer 104 is advantageously insensitive to a slowly varying direct current (DC) component of the analog signal 121.

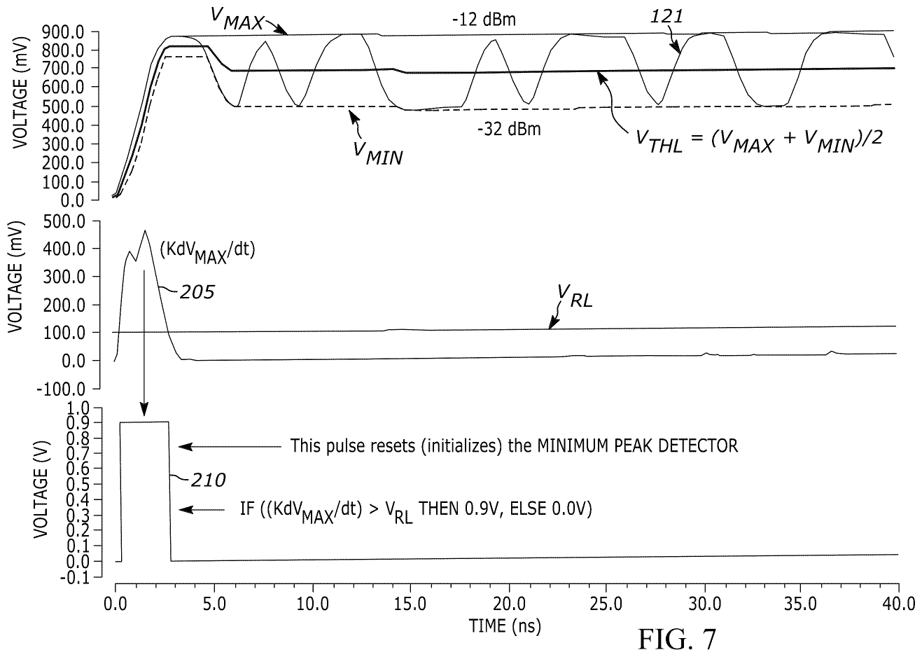

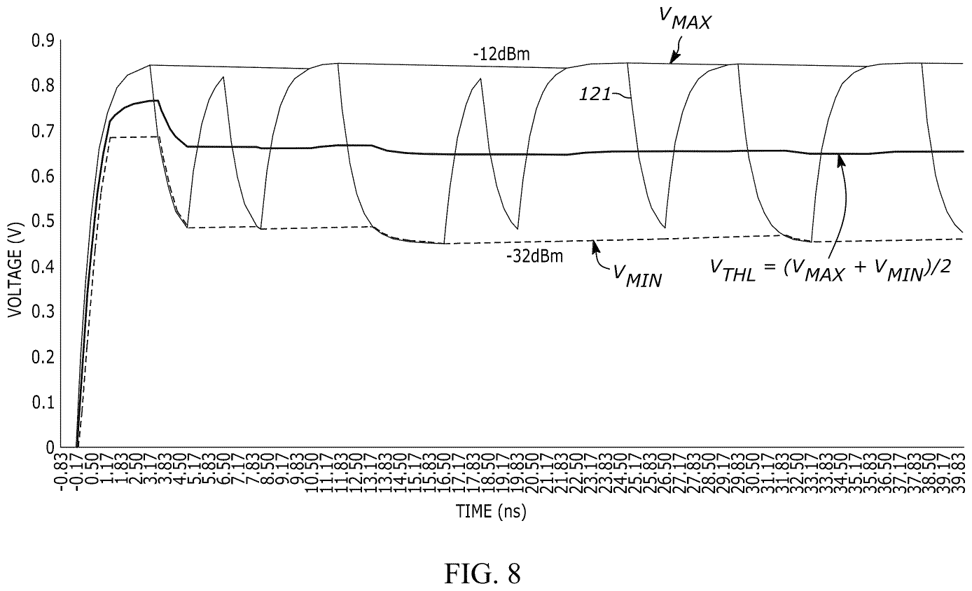

The output terminal 221 of the maximum peak detector 201 is coupled to an input terminal 223 of the differentiator 203. An output signal 205 of the differentiator 203 is responsive to a rate of change of an output signal V_{MAX} of the maximum peak detector 201. The output signal 205 of the differentiator 203 is KdV_{MAX}/dt, where K is a gain factor which is expressed in seconds. Note that dV_{MAX}/dt peaks to approximately 1 GV/s at the beginning of the packet; therefore, K is approximately 0.5 ns. The aforementioned values are based on a simulation some results of which are shown in FIGS. 7 and 8. The output signal 205 of the differentiator 203 is an analog voltage directly proportional to, or linear with, a rate of change of V_{MAX}. An output voltage of the differentiator 203 is highest when V_{MAX} changes most rapidly. As a result, the differentiator 203 detects a start of a packet embedded in an analog baseband signal 121. The output signal 205 of the differentiator 203 is used to initialize the minimum peak detector 202 to minimize a settling time of the threshold estimation.

The comparator 204 includes a first input terminal 231 for receiving the output signal 205 of the differentiator 203, and a second input terminal 232 coupled to a constant voltage source 215 having a preselected voltage, V_{RL} (see FIG. 7). The comparator 204 outputs a pulse 210 only when a voltage of the output signal 205 of the differentiator 203 is higher than the voltage V_{RL} of the constant voltage source 215. In one embodiment, an output voltage of the comparator 204 is 0.9V for approximately 3 ns (see FIG. 7) when the voltage of the output signal 205 of the differentiator 203 is higher than the voltage V_{RL} of the constant voltage source 215. Otherwise, the output voltage of the comparator 204 is 0V. The output voltage of the comparator 204 is as follows: IF (KdV_{MAX}/dt)>V_{RL} THEN 0.9V, ELSE 0.0V. The voltage V_{RL} is preselected to be high enough so that a false pulse from the comparator 204 does not occur. The voltage V_{RL} is also preselected to be low enough to ensure that the pulse 210 from the comparator 204 does occur at the beginning of a packet. In one embodiment, the constant voltage source 215 produces a DC voltage of 100 mV which voltage is preselected typically by simulation of the circuitry.

In one embodiment, a first-order low-pass filter (not shown) is inserted between the differentiator 203 and the comparator 204 to avoid false triggers of the comparator. In another embodiment, hysteresis (not shown) is added in the comparator 204 to avoid false triggers of the comparator.

A start of a packet is detected by differentiating an output of the maximum peak detector 201 to initialize the minimum peak detector 202. Initializing the minimum peak detector 202 minimizes a settling time of an estimation of the slicing level/threshold.

The configuration of the fast-settling threshold estimator 102 illustrated in FIG. 2 is used when a polarity of the analog signal 121 is as shown in FIGS. 7 and 8. If the polarity of the analog signal 121 is opposite to the polarity shown in FIGS. 7 and 8, then the input terminal of the differentiator 203 is coupled to the output terminal of the minimum peak detector 202 (instead of to the output terminal of the maximum peak detector 201) and the output of the comparator 204 is coupled to the maximum peak detector 201 (instead of to the minimum peak detector 202). Otherwise, the operation is analogous.

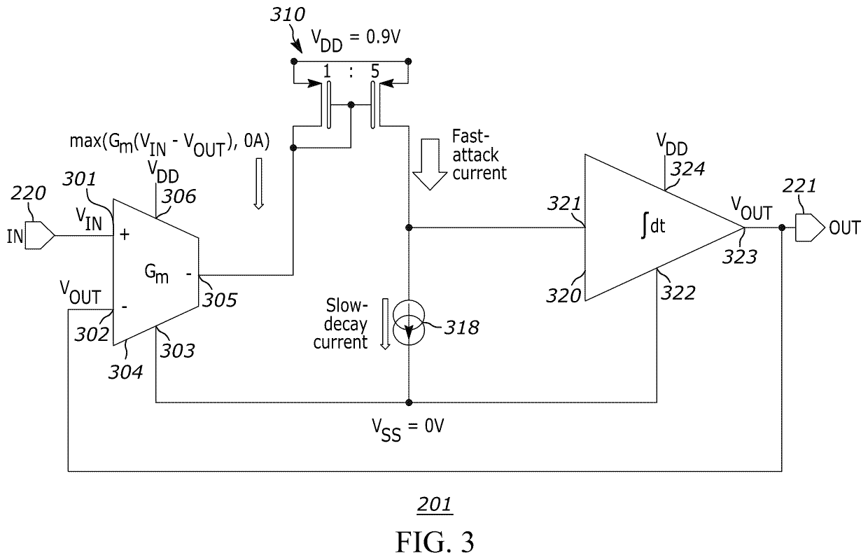

FIG. 3 is a simplified functional block diagram of the maximum peak detector 201, in accordance with one embodiment of the invention. The maximum peak detector 201 determines a peak level of an analog signal such as the analog signal 121 outputted by the RF receiver 103. The maximum peak detector 201 includes a transconductance amplifier 304 having a positive input terminal 301 coupled to the input terminal 220 of the maximum peak detector 201, a negative input terminal 302 coupled to the output terminal 221 of the maximum peak detector, a terminal 303 coupled to ground potential V_{SS}, a terminal 306 coupled to a supply voltage V_{DD} and a (negative) output terminal 305. The transconductance amplifier 304 contains a voltage-controlled current circuit coupled internally to output terminal 305. The transconductance amplifier 304 compares V_{OUT}, which is an output signal of the maximum peak detector 201, to V_{IN}, which is a voltage of the analog signal 121. The transconductance amplifier 304 is configured to generate a current Gₘ(V_{IN}−V_{OUT}), where Gₘ is the transconductance. Therefore, the transconductance amplifier 304 generates a positive current only when V_{OUT} is lower than V_{IN}; otherwise, the transconductance amplifier attempts to generate a negative current, which is, however, blocked by the rectifying current mirror 310, i.e., the current is 0A. Therefore, the transconductance amplifier 304 generates a positive current only when V_{OUT} is lower than the voltage of the analog signal 121; otherwise, the transconductance amplifier would generate a negative current, which is, however, blocked by the rectifying current mirror, i.e., the current is 0A. In one embodiment, Gₘ has a value of approximately 1 mA/V. In one embodiment, V_{OUT} has a value between 0V and 1V, and V_{IN} has a value between 0V and 1V. In one embodiment, an absolute maximum output current of the transconductance amplifier 304 is approximately 200 μA. When the fast-settling threshold estimator 102 is in attack mode, in one embodiment, (V_{IN}−V_{OUT}) is less than 0.2V, and in most cases is less than 4 mV. Attack mode is a situation when there is attack current flowing, i.e., when (V_{IN}−V_{OUT})>0. When a peak detector 201, 202 is in decay mode, in one embodiment, (V_{IN}−V_{OUT}) is approximately −400 mV as in the example simulation shown in FIGS. 7 and 8, but can be as large as −900 mV in other examples that are not shown. Decay mode is a situation when there is only decay current flowing, so when (V_{IN}−V_{OUT})<0. Decay mode and attack mode are mutually exclusive. A peak detector is either in decay mode or in attack mode.

The maximum peak detector 201 includes a current mirror 310 coupled to the output terminal 305 of the transconductance amplifier 304. The current mirror 310 comprises an input transistor having a source electrode coupled to V_{DD}, a drain electrode coupled to the output terminal 305 and having a gate electrode. The current mirror 310 further comprises an output transistor having a source electrode coupled to V_{DD}, a gate electrode coupled to the gate electrode of the input transistor, and having a drain electrode. The current mirror 310 rectifies and amplifies the output current of the transconductance amplifier 304. In one embodiment, the amplification factor of the current mirror 310 is “5”, and when the maximum peak detector 201 is in attack mode, the current mirror 310 outputs a maximum fast-attack current of approximately 1 mA. In such embodiment, when the maximum peak detector 201 is in attack mode, the current mirror 310 outputs a fast-attack current of approximately maximum 1 mA, and in most cases not more than 20 μA. There is no current from the current mirror 310 when the output current of the transconductance amplifier 304 is zero.

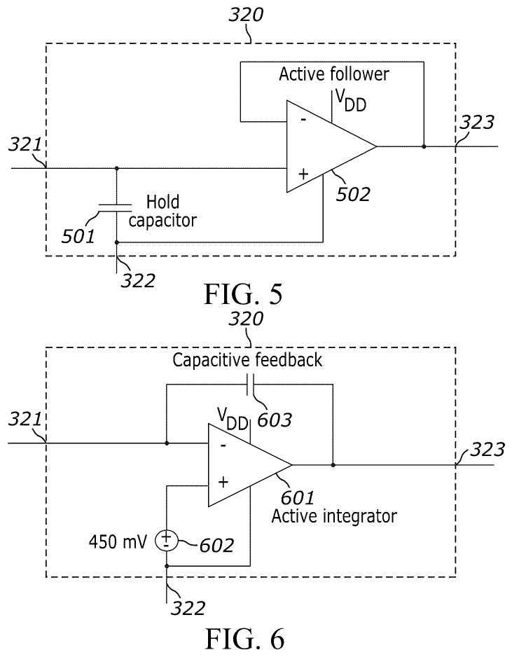

The maximum peak detector 201 includes a slow decay current source 318 coupled between the drain electrode of the output transistor of the current mirror 310 and ground potential. In one embodiment, a fixed value of the slow decay current source 318 is preselected to be approximately 1 μA. The maximum peak detector 201 includes an integrator 320 having an input terminal 321 coupled to the output terminal of the current mirror 310, a terminal 322 coupled to ground potential, an output terminal 323 coupled to the output terminal 221 of the maximum peak detector 201, and a terminal 324 coupled to V_{DD}. The integrator 320 integrates its input current and delivers the result as an output voltage. A positive component of the output current from the transconductance amplifier 304, after being amplified by current mirror 310 with a factor of “5”, feeds a capacitor 501 (see FIG. 5) in the integrator 320.

A voltage across the capacitor constitutes V_{MAX}, the output signal of the maximum peak detector 201. The maximum peak detector 201 includes a fast attack, or charge, current which is generated by the current mirror 310 when the transconductance amplifier 304 outputs a current. The fast attack current allows the voltage across the capacitor to advantageously quickly increase when V_{MAX} is lower than the voltage of the analog signal 121. When the output current of the transconductance amplifier 304 is zero, there is no attack current, and the capacitor is slowing discharged by a small decay current generated by the slow decay current source 318. The voltage of the capacitor is buffered by an operational amplifier (see FIG. 5) connected as an active voltage follower in the integrator 320. The operational amplifier prevents the capacitor from being loaded by other parts of the circuit, allowing the capacitor to maintain its voltage. As the capacitor discharges, the voltage outputted by the maximum peak detector 201 advantageously only slowly goes down. As a result, V_{MAX}, the output voltage of the maximum peak detector 201 advantageously tends to almost hold to a maximum of the input voltage, i.e., the analog voltage 121, of the maximum peak detector.

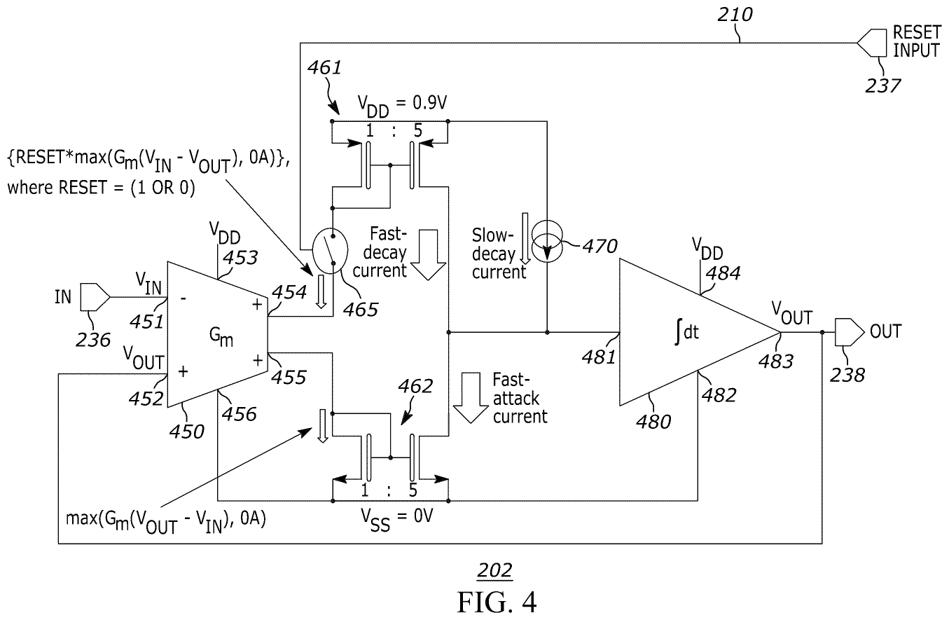

FIG. 4 is a simplified functional block diagram of the minimum peak detector 202, in accordance with one embodiment of the invention. The minimum peak detector 202 determines a minimum voltage level of the analog signal 121 advantageously more quickly than known peak detectors by using a RESET signal to initialize, or precharge, the minimum peak detector. Because the minimum peak detector determines the minimum value of its input voltage, the minimum peak detector is initialized with a relatively high voltage but normally less than V_{DD}. This means that the capacitor 501 is precharged to the relatively high voltage level at initialization of the minimum peak detector. The minimum peak detector 202 includes a transconductance amplifier 450 located at an input of the minimum peak detector 202. The transconductance amplifier 450 has a negative input terminal 451 for receiving the analog signal 121, a positive input terminal 452 coupled to the output terminal 238 of the minimum peak detector 202, a third terminal 453 coupled to V_{DD}, a fourth terminal 454 coupled to a first current mirror 461 through a switch 465, a fifth terminal 455 coupled to a second current mirror 462, and a sixth terminal 456 coupled to ground potential or V_{SS}.

The first current mirror 461 has an input transistor and an output transistor. The transconductance amplifier 450 contains a first voltage-controlled current circuit internally coupled to the fourth terminal 454. A sinking current occurs from the first current mirror 461 through the switch 465, when conductive, to the fourth terminal 454 when Gₘ(V_{IN}−V_{OUT}) is positive. In one embodiment, a maximum sinking current to the fourth terminal 454 is approximately 200 μA. The sinking current from the first current mirror 461 to the fourth terminal 454 occurs under the following conditions: RESET=1 AND Gₘ(V_{IN}−V_{OUT}) is positive.

The second current mirror 462 has an input transistor and an output transistor. The transconductance amplifier 450 contains a second voltage-controlled current circuit internally coupled to the fifth terminal 455. A sourcing current is outputted from the fifth terminal 455 to the second current mirror 462 when Gₘ(V_{OUT}−V_{IN}) is positive. In one embodiment, a maximum sourcing output current from the fifth terminal 455 is approximately 200 μA. A sinking current occurs from the second current mirror 462 to the fifth terminal 455 when Gₘ(V_{OUT}−V_{IN}) is negative. However, that sinking current is blocked by the input transistor of current mirror 462, which acts as a rectifying diode (gate connected to drain). This is the intended rectification property of the current mirror to distinguish attacking from decaying. Either a sourcing current Gₘ(V_{OUT}−V_{IN}) occurs from the fifth terminal 455 to the second current mirror 462, or no current occurs between the fifth terminal 455 and the second current mirror 462, depending upon polarity, or sign, of Gₘ(V_{OUT}−V_{IN}). The output current from the fourth terminal 454 and the output current from the fifth terminal 455 of the transconductance amplifier 450 have equal polarity and phase, as far as the transconductance amplifier 450 is concerned. However, the output current from the fourth terminal 454 or the output current from the fifth terminal 455 might be blocked by one of the rectifying current mirrors 461, 462 depending on direction of the output current, or the output current might be blocked by the switch 465 when it is non-conducting.

The switch 465 is coupled between the fourth terminal 454 of the transconductance amplifier 450 and the input transistor of the first current mirror 461. When the minimum peak detector 202 receives a RESET signal, i.e., pulse 210, from the comparator 204, the switch 465 is conducting. Then, the current Gₘ(V_{IN}−V_{OUT}) from the fourth terminal 454 causes the first current mirror 461 to produce a fast-decay current, assuming the current Gₘ(V_{IN}−V_{OUT}) is positive. The fast-decay current is produced at a drain terminal of the output transistor of the first current mirror 461. In one embodiment, the switch 465 is a transistor that has a control electrode coupled to the reset input terminal 237 of the minimum peak detector 202 for receiving the pulse 210 from the comparator 204; the switch also has one conducting electrode coupled to a drain terminal of the input transistor of the current mirror 461 and another conducting electrode coupled to the fourth terminal 454 of the transconductance amplifier 450.

A response time of the minimum peak detector 202 is small compared to the bit time, i.e., the inverse of the bit rate.

However, most of the time during a packet, the switch 465 is non-conducting; therefore, a potential current Gₘ(V_{IN}−V_{OUT}) to the fourth output terminal 454 is blocked by the switch 465 and does not cause the first current mirror 461 to produce a fast-decay current (or any current). The current to output terminal 454 is amplified by the first current mirror 461. In one embodiment, the first current mirror 461 has an amplification factor of “5”. In one embodiment, the fast-decay current approximately peaks to 0.6 mA.

The minimum peak detector 202 includes a non-inverting integrator 480 having an input terminal 481 coupled to an output terminal of the first current mirror 461, a terminal 482 coupled to ground potential, or V_{SS}, an output terminal 483 coupled to the output terminal 238 of the minimum peak detector 202 and a terminal 484 coupled to V_{DD}. The non-inverting integrator 480 includes a capacitor 501 (see FIG. 5). The current to output terminal 454 is rectified by the first current mirror 461 meaning that the fast-decay current is positive only and feeds, i.e., charges, the capacitor 501 in the integrator 480. The fast-decay current is propagated when the pulse 210 turns on switch 465 to drive the first current mirror 461, assuming Gₘ(V_{IN}−V_{OUT}) is positive. That way, the voltage of the capacitor 501 quickly increases when the RESET signal enables current to flow through current mirror 461.

During attack mode, the transconductance amplifier 450 provides a positive current Gₘ(V_{OUT}−V_{IN}) at the terminal 455 as long as an output voltage of the minimum peak detector 202 is higher than the voltage of the analog signal 121. In one embodiment, Gₘ has a value of approximately 1 mA/V. In one embodiment, V_{OUT} has a value between 0V and 1V, and V_{IN} has a value between 0V and 1V. In response to the current to output terminal 454, the first current mirror 461 outputs a fast-decay current when the switch 465 is conductive which occurs when the RESET signal is high. In one embodiment, the fast-decay current is 0.6 mA and lasts for 3 ns. The minimum peak detector 202 includes a slow decay current source 470 coupled between V_{DD} and the input terminal 481 of the integrator 480. A small slow decay current charges the capacitor (see FIGS. 5 and 6) in the integrator 480 continuously but only slowly. That way, V_{MIN}, the output voltage of the minimum peak detector 202, advantageously tends to almost hold to a minimum input voltage. An output current of the first current mirror 461 is a fast-decay current which has a same direction as the slow decay current source 470. The fast-decay current only occurs during reset of the minimum peak detector 202. As shown in the example of FIG. 7, reset of the minimum peak detector 202 occurs for only the first approximately 3 ns of a packet.

The minimum peak detector 202 includes a second current mirror 462 coupled between the fifth terminal 455 of the transconductance amplifier 450 and ground potential, or V_{SS}. The transconductance amplifier 450 outputs the current (max Gₘ(V_{OUT}−V_{IN}), 0A) from the fifth terminal 455. In response to the current from the fifth terminal 455 of the transconductance amplifier 450, the second current mirror 462 outputs a fast attack current. This current is rectified meaning that it is positive only, as indicated by the direction of the fast-attack-current arrow in FIG. 4, and it discharges the capacitor in the integrator 480. That way, a voltage of the capacitor in the integrator 480 quickly decreases as long as the voltage at the output terminal 238 of the minimum peak detector 202 remains higher than the voltage at the first input terminal 236 of the minimum peak detector. In one embodiment, the fast attack current is less than 0.3 mA (and less than 50 μA most of the time) and lasts for 3 ns or less. In one embodiment, the second current mirror 462 has an amplification factor of “5”.

FIG. 5 is a simplified functional block diagram of a first example of an integrator 320 and 480 in accordance with one embodiment of the invention. FIG. 5 is an example of an integrator 320 and 480 comprising a capacitor 501 followed by an active follower circuit including an operational amplifier 502. The voltage of the capacitor 501 is buffered by the operational amplifier 502 connected as an active voltage follower. During reset, a positive component of the output current from the fourth terminal 454 of the transconductance amplifier 450 feeds the capacitor 501 through the first current mirror 461. In one embodiment, a size of capacitor 501 is 1 ρF. A voltage across the capacitor 501 constitutes V_{MAX}, the output signal of the maximum peak detector 201, or constitutes V_{MIN}, the output signal of the minimum peak detector 202. During attack mode of the maximum peak detector 201, the capacitor 501 in integrator 320 is charged quickly, but during attack mode of the minimum peak detector 202, the capacitor is discharged quickly. Other integrator architectures could be used.

With an inverting integrator, the attack current source and the decay current source in the peak detector must be swapped to end up with negative (instead of positive) feedback to avoid an unstable circuit.

FIG. 6 is a simplified functional block diagram of a second example of an integrator 320 and 480 in accordance with one embodiment of the invention. FIG. 6 is an example of an inverting active integrator comprising an operational amplifier 601, and a voltage source 602 with capacitive feedback 603. Other inverting integrator architectures could be used.

FIGS. 7 and 8 illustrate graphs of signals present in a simulation of the fast-settling threshold estimator shown in FIG. 2 using a semi-logarithmic RF-envelope detector; however, noise is not included in the simulation, so it appears from the simulation results that V_{THL}=(V_{MAX}+V_{MIN})/2. When optimum values of first resistor 241 and second resistor 242 are used with a semi-logarithmic RF-envelope detector based on the presence of noise, first resistor 241 and second resistor 242 would not be equal and V_{THL}≠(V_{MAX}+V_{MIN})/2. The graphs in FIGS. 7 and 8 illustrate that the fast-settling threshold estimator 102 functions when the amplitude of the RF analog signal 101 is binary modulated between −12 dBm and −32 dBm as measured at the input to the RF low-noise amplifier 110, wherein the 20 dB difference is equivalent to a factor of ten in signal strength (voltage or current). However, the fast-settling threshold estimator 102 is not limited to functioning only within the aforementioned range of signal strength. FIG. 8 illustrates an example of a packet with a four-bit preamble of “1101”. The fast-settling threshold estimator 102 is also compatible with the BLUETOOTH® protocol which has a preamble that starts with “1010”. However, the preamble of “1101” used in the simulation results shown in FIGS. 7 and 8 demonstrates that the fast-settling threshold estimator 102 is not limited for use with the preamble of the BLUETOOTH protocol but is also effective for use with other preambles.

Referring now specifically to FIG. 8, the voltage of the output signal V_{MAX} of the maximum peak detector 201 follows the voltage of the analog signal 121 for about the first 3 ns of the packet because the maximum peak detector is initially in attack mode and the large fast attack current causes V_{MAX}, the output signal of the maximum peak detector, to increase in unison with the analog signal. Thereafter, V_{MAX} slowly decreases due to the presence of the small slow decay current. However, upon occurrence of V_{MAX} being lower than the analog signal 121, at about 10 ns after start of the packet, V_{MAX} advantageously quickly rises to the voltage of the analog signal 121 because the large fast attack current becomes activated. The data rate of the signal shown in FIG. 8 is 600 Mb per second.

Referring now specifically to FIG. 7, the voltage of V_{MIN}, the output signal of the minimum peak detector 202, advantageously follows the voltage of the analog signal 121 while pulse 210, the output signal of comparator 204, is high. In the example simulation of FIG. 7, pulse 210 is high for about the first 3 ns of the packet. In accordance with the invention, the output signal of the comparator 204 is high because the differentiator 203 detected, for about the first 3 ns of the packet, a high rate of change in V_{MAX}, the voltage of the output signal of the maximum peak detector 201. As discussed hereinabove, the high output signal of the comparator 204 causes a large fast-settling, or fast-decay, current to occur in the minimum peak detector 202 thereby advantageously quickly producing a large voltage at the output terminal 238 of the minimum peak detector. As a result, the minimum peak detector 202 tracks the analog signal 121 better than known threshold estimators. The large fast-decay current has a same direction as the small slow-decay current because current mirror 461 and slow decay current source 470 are in parallel in the minimum peak detector 202. Both the fast-decay current and the slow-decay current charge the capacitor 501, resulting in an output voltage (V_{MIN}) increase over time. When pulse 210, the output signal of the comparator 204, is low, the large fast-settling current stops occurring. At this juncture, V_{MIN} slowly rises due to the presence of the small decay current in the minimum peak detector 202. From approximately 4 ns to approximately 5 ns, a large fast-attack current causes V_{MIN} to track a decreasing analog signal 121. Thereafter, V_{MIN} slowly rises due to the presence of the small decay current in the minimum peak detector 202. However, upon occurrence of V_{MIN} being higher than the analog signal 121, V_{MIN} advantageously quickly falls to the voltage of the analog signal 121 because the large fast attack current becomes activated.

In another embodiment (not shown), the small decay current is a function of (V_{IN}−V_{OUT}) instead of being fixed by the slow decay current source 318 and 470. Making the small decay current proportional with (V_{IN}−V_{OUT}) would lead to a fixed time constant, instead of a fixed slope (V/s) as when the small decay current is based on the slow decay current source 318 and 470 which are fixed. A fixed time constant would make the peak detectors 201 and 202 less dependent on an actual signal amplitude/swing.

In one embodiment, the fast-settling threshold estimator 102 achieves an attack/decay ratio of about 1K. The attack/decay ratio of about 1K improves a bit error rate during a packet without needing a long preamble at the beginning of the packet.

In the embodiment of the fast-settling threshold estimator 102 shown in FIG. 2, only the output of the maximum peak detector 201 is differentiated. In another embodiment (not shown) of the fast-settling threshold estimator 102, only the output of the minimum peak detector 202 is differentiated and via a comparator, a reset input terminal of the maximum peak detector 201 is controlled. In yet another embodiment (not shown) of the fast-settling threshold estimator 102, the output of the maximum peak detector 201 and the output of the minimum peak detector 202 are differentiated.

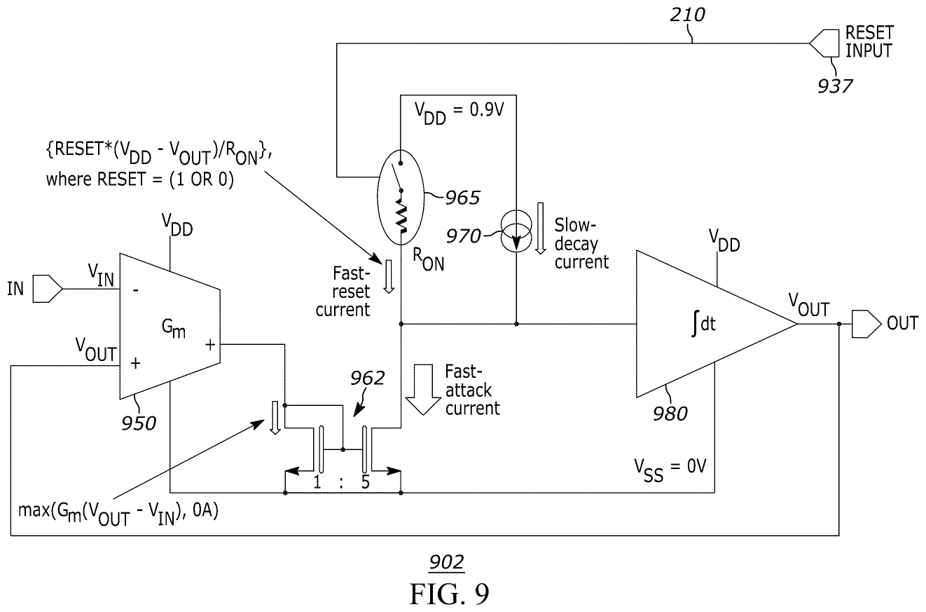

FIG. 9 is a simplified functional block diagram of a minimum peak detector 902. The fast-decay current in FIG. 4 has been replaced with a fast-reset current in FIG. 9. As long as RESET=0, both the fast-decay current in FIG. 4 and the fast-reset current in FIG. 9 are zero, and the operation of the minimum peak detector 202 is similar to the operation of the minimum peak detector 902.

The minimum peak detector 902 includes a transconductance amplifier 950 having an input terminal for receiving the analog signal 121, an input terminal coupled to an output terminal of the minimum peak detector, a terminal coupled to V_{DD}, a terminal coupled to V_{SS}, and an output terminal. The minimum peak detector 902 includes a switch 965 with one end coupled to V_{DD}. The switch has a small on-resistance R_{ON}. In one embodiment, R_{ON} has a value in the order of 0.5KΩ. The minimum peak detector 902 includes a non-inverting integrator 980 having an input terminal coupled to another end of the switch 965, a terminal coupled to V_{DD}, a terminal coupled to V_{SS}, and an output terminal. The minimum peak detector 902 includes a slow-decay current source 970 coupled between V_{DD} and the input terminal of the integrator 980. The minimum peak detector 902 includes a current mirror 962 having an input transistor and an output transistor. The input transistor has a drain electrode coupled to the output terminal of the transconductance amplifier 950 and a source electrode coupled to V_{SS}. The output transistor has a drain electrode coupled to the input terminal of the integrator 980 and a source electrode coupled to V_{SS}. A control terminal of the switch 965 is coupled to a reset input terminal 937. The state of the switch 965 is controlled by the pulse 210.

Assuming that the input voltage V_{IN} is decreasing over time and that it is smaller than the output voltage V_{OUT}, the operation of the minimum peak detector 902 is as follows: If the input voltage V_{IN} is smaller than the output voltage V_{OUT}, then the transconductance amplifier 950 outputs, i.e., sources, an output current, which is proportional to a difference between V_{OUT} and V_{IN}, to the input transistor of the current mirror 962. The output current is expressed as {max(Gₘ(V_{OUT}−V_{IN}), 0A)}. The current mirror 962 amplifies, i.e., multiplies, the output current with a factor of “5”, resulting in a large attack current at the output transistor of the current mirror 962 which discharges the capacitor 501 of the integrator 980. Because the attack current is large, the aforementioned discharge is fast, and therefore the large attack current is called a fast-attack current. The continuously-flowing slow-decay current counteracts this discharge, but because the slow-decay current is very small, this effect is negligible. The output voltage V_{OUT} equals the voltage across the capacitor 501. Because the capacitor 501 is discharged rapidly, the output voltage V_{OUT} rapidly decreases and tends to follow the input voltage V_{IN}. However, the tracking is not exact because a small voltage difference between V_{OUT} and V_{IN} remains. This small voltage difference is needed for the transconductance amplifier 950 to generate its output current, which is proportional to this small voltage difference, and therefore the discharging of the capacitor 501 continues. The aforementioned process stops when the input voltage V_{IN} has reached a local minimum. In this way, the output voltage V_{OUT} keeps track of the minimum value of the input voltage V_{IN}. The output voltage V_{OUT} can be regarded as an estimate of the minimum value of the input voltage V_{IN}. It approximately equals the minimum value of the input voltage V_{IN} found so far.

Assuming that at this juncture, the input voltage V_{IN} starts to increase; and, therefore, it will be larger than the output voltage V_{OUT}. Consequently, the transconductance amplifier 950 attempts to reverse the direction of its output current. Instead of sourcing an output current, transconductance amplifier 950 attempts to sink an output current. However, the input transistor of the current mirror 962, which is configured as a rectifying diode (gate connected to drain), blocks this attempt and as a result, the output current of the transconductance amplifier 950 becomes zero. Therefore, the attack current, which is the amplified version of the output current of the transconductance amplifier 950, also becomes zero. Now the only current left, is the small decay current. The small decay current slowly charges the capacitor 501. As a result, the output voltage V_{OUT} slowly increases. Because a rate of change of the voltage across the capacitor 501 versus time is only slightly positive, the output voltage V_{OUT} tends to hold onto the minimum value found so far. This behavior can be considered a (leaky) memory function.

In a next cycle of the analog signal 121, the input voltage V_{IN} could again become lower than the output voltage V_{OUT}, which approximately equals the minimum value of the input voltage V_{IN} found so far, and the aforesaid process repeats.

Without additional measures, the minimum peak detector 902 would have a long settling time at the beginning of a packet caused by its slow decay due to the small decay current. The long settling time is significantly reduced by utilizing a RESET signal that is controlled by the (binary quantized) time derivative of the output signal 205 of the maximum peak detector 201. The minimum peak detector 902 receives the RESET signal at the reset input terminal 937.

Resetting the minimum peak detector 902 means initializing the output voltage of the minimum peak detector to a high voltage level. If the RESET signal becomes high, then the switch 965 becomes conductive and the input voltage of the integrator 980 is pulled up towards V_{DD}. The output voltage V_{OUT} closely follows the input voltage of the integrator 980 because of a voltage buffer/follower in the integrator. The slow-decay current contributes constructively, but its contribution is negligible because it is a very small current. Because the reset current is only limited by the small on-resistance R_{ON} of the switch 965, it is a large current; and therefore, capacitor 501 is charged quickly. Very soon thereafter, the output voltage V_{OUT} becomes larger than the input voltage V_{IN} and, as a result, the minimum peak detector 902 starts attacking. Therefore, a value of the output voltage V_{OUT} becomes between V_{DD} and V_{IN}. The value of the output voltage V_{OUT} in the minimum peak detector 902 is slightly higher than that in the minimum peak detector 202 where it is slightly below V_{IN} (fast-decay mode during reset). The fast-reset current is expressed as {RESET*(V_{DD}−V_{OUT})/R_{ON}}, where RESET=(1 or 0).

Any additional current consumption due to the reset current and the attack current flowing at the same time, is negligible because the RESET signal is only one narrow pulse, pulse 210, at a beginning of the packet. In one embodiment (not shown) a switch is inserted in the output lead of the transconductance amplifier 950. Such switch is controlled by the RESET signal and is non-conductive during reset, to prevent an attack current during reset. The minimum peak detector 902 consumes less current than the minimum peak detector 202 because the minimum peak detector 902 uses a single-output transconductance amplifier instead of a dual-output transconductance amplifier, thereby reducing bias-current consumption.

The minimum peak detector 902 also works with an inverting integrator, after swapping the current sources and the switch. With the minimum peak detector 902, the reset current is independent of V_{IN}.

If the input voltage V_{IN} is smaller than the output voltage V_{OUT}, then the transconductance amplifier 950 sources an output current proportional to the difference between V_{OUT} and V_{IN}. The output current is equal to this voltage difference times a transconductance Gₘ of approximately 1 mA/V. If the input voltage V_{IN} equals the output voltage V_{OUT}, then the transconductance amplifier 950 does not output any output current. If the input voltage V_{IN} is larger than the output voltage V_{OUT}, then the transconductance amplifier 950 attempts to sink an output current. However, the input transistor of the current mirror 962, which is configured as a rectifying diode (gate connected to drain), blocks this attempt and as a result, the output current of the transconductance amplifier 950 is zero.

The current mirror 962 rectifies and amplifies the output current of the transconductance amplifier 950. The output current of the transconductance amplifier 950 is amplified, i.e., multiplied with a factor of “5” by the current mirror 962 and the product of this multiplication is the output current of the current mirror, which is the fast-attack current.

The slow-decay current source 970 generates a small decay current of approximately 1 μA in one embodiment.

If the RESET signal is low, then the switch 965 is non-conductive and there is no current through the switch 965. If the RESET signal is high (at the beginning of a data packet), then the current through the switch 965 is the fast-reset current and is proportional to a difference between the supply voltage V_{DD} and the input voltage of the integrator 980 (which equals V_{OUT} due to an internal voltage buffer/follower of the integrator). The fast-reset current is equal to this voltage difference divided by the on-resistance R_{ON} of the switch 965 which, in one embodiment, is approximately 0.5KΩ.

According to Kirchhoff's current law, the input current of the integrator 980 is equal to the slow-decay current plus the fast-reset current minus the fast-attack current. The input current of the integrator 980 is integrated by capacitor 501. In one embodiment, capacitor 501 has a value of approximately 1 ρF. The voltage across the capacitor 501 is buffered by the internal voltage buffer/follower to prevent disturbing charge currents or discharge currents due to an external load (not shown) of the minimum peak detector 202. The output voltage V_{OUT} is equal to the voltage across capacitor 501. The rate of change (V/s) of the output voltage V_{OUT} is equal to the input current of the integrator 980 divided by the capacitance of capacitor 501.

During attack, the output voltage V_{OUT} tracks the input voltage V_{IN}, in good approximation. By reasoning backward, it follows that the difference between V_{OUT} and V_{IN}, which can be considered as a (dynamic) tracking error, is approximately equal to the rate of change (V/s) of the input voltage V_{IN} multiplied by the capacitance of capacitor 501 and divided by five times the transconductance Gₘ.

A fast-settling threshold estimator 102 for determining a fast-settling threshold voltage V_{THL} comprises a maximum peak detector 201 for receiving an analog signal 121, the analog signal containing digital data, wherein the maximum peak detector produces at its output terminal an estimate of a maximum value of the analog signal within a predetermined time range; a differentiator 203 coupled to the maximum peak detector, wherein the differentiator produces an output voltage having a value responsive to a change in the estimate of the maximum value of the analog signal; a constant voltage source 215 having a preselected voltage; a comparator 204 having a first input terminal 231 coupled to the differentiator and a second input terminal 232 coupled to the constant voltage source, wherein the comparator outputs a pulse 210 when the output voltage of the differentiator is greater than the preselected voltage; a minimum peak detector 202 having a first input terminal 236 for receiving the analog signal and a reset input terminal 237 for receiving the pulse, wherein the pulse resets the minimum peak detector and, after being reset, the minimum peak detector produces at its output terminal an estimate of a minimum value of the analog signal within a predetermined time range; and an averaging circuit 235 coupled to the maximum peak detector and to the minimum peak detector for producing a weighted average of the estimate of the maximum value of the analog signal and the estimate of the minimum value of the analog signal, wherein the weighted average is the fast-settling threshold voltage.

An electronic circuit 100 for determining a slicing level of digital data in an analog signal comprises a bit-slicing voltage comparator 104 having a positive input terminal 131 for receiving an analog signal 121 containing digital data, a negative input terminal 132, and an output terminal for outputting a binary signal based on the digital data; and a fast-settling threshold estimator 102 for producing a fast-settling threshold voltage V_{THL}, the fast-settling threshold estimator having an input terminal 126 for receiving the analog signal and an output terminal 128 coupled to the negative input terminal of the bit-slicing voltage comparator. The fast-settling threshold estimator includes a maximum peak detector 201 having an input terminal 220 for receiving the analog signal and having an output terminal 221, wherein the maximum peak detector produces at its output terminal an estimate of a maximum value of the analog signal; a differentiator 203 having an input terminal 223 coupled to the output terminal of the maximum peak detector, and having an output terminal, wherein the differentiator produces an output signal 205 responsive to a change in the analog signal; a second comparator 204 having a first input terminal 231 coupled to the differentiator and a second input terminal 232 coupled to a constant voltage source 215 having a preselected voltage and having an output terminal, wherein the second comparator outputs a pulse 210 when a voltage of the output signal of the differentiator is greater than the preselected voltage; and a minimum peak detector 202 having a first input terminal 236 for receiving the analog signal and a reset input terminal 237 for receiving the pulse, wherein the pulse resets the minimum peak detector and, after being reset, the minimum peak detector outputs at an output terminal an estimate of a minimum value of the analog signal. The fast-settling threshold estimator also includes an averaging circuit 235 coupled to the maximum peak detector and to the minimum peak detector for producing a weighted average of the estimate of a maximum value of the analog signal and the estimate of a minimum value of the analog signal, wherein the weighted average is the fast-settling threshold voltage V_{THL} of a slicing level of the digital data.

A radio frequency (RF) receiver 103 comprises an RF low-noise amplifier 110 coupled to an antenna 112 for receiving digital data in an RF analog signal 101; an RF-envelope detector 114 coupled to the RF low-noise amplifier for downmixing the RF analog signal and for outputting a baseband analog signal; a semi-logarithmic baseband transimpedance amplifier 116 coupled to the RF-envelope detector; a baseband low-pass filter 120 having an input coupled to the semi-logarithmic baseband transimpedance amplifier and having an output terminal; a fast-settling threshold estimator 102 having an input terminal 126 coupled to the output terminal of the baseband low-pass filter and having an output terminal 128 for outputting a fast-settling threshold voltage V_{THL}; and a bit slicer 104 having a first input terminal 131 coupled to the output terminal of the baseband low-pass filter and a second input terminal 132 coupled to the output terminal of the fast-settling threshold estimator, wherein the bit slicer outputs a binary signal responsive to the digital data in the analog RF signal and responsive to the fast-settling threshold voltage.

One or more embodiments of the present disclosure may include features recited in the following numbered clauses:

1. A fast-settling threshold estimator for determining a fast-settling threshold voltage, comprising: a maximum peak detector for receiving an analog signal, the analog signal containing digital data, wherein the maximum peak detector produces at its output terminal an estimate of a maximum value of the analog signal within a predetermined time range; a differentiator coupled to the maximum peak detector, wherein the differentiator produces an output voltage having a value responsive to a change in the estimate of the maximum value of the analog signal; a constant voltage source having a preselected voltage; a comparator having a first input terminal coupled to the differentiator and a second input terminal coupled to the constant voltage source, wherein the comparator outputs a pulse when the output voltage of the differentiator is greater than the preselected voltage; a minimum peak detector having a first input terminal for receiving the analog signal and a reset input terminal for receiving the pulse, wherein the pulse resets the minimum peak detector and, after being reset, the minimum peak detector produces at its output terminal an estimate of a minimum value of the analog signal within a predetermined time range; and an averaging circuit coupled to the maximum peak detector and to the minimum peak detector for producing a weighted average of the estimate of the maximum value of the analog signal and the estimate of the minimum value of the analog signal, wherein the weighted average is a fast-settling threshold voltage.

2. The fast-settling threshold estimator of claim 1, wherein the differentiator outputs a voltage that is linear with a rate of change in the analog signal.

3. The fast-settling threshold estimator of claim 2, including a bit slicer wherein, based in part on the fast-settling threshold voltage, the bit slicer outputs a binary signal corresponding to the digital data.

4. The fast-settling threshold estimator of claim 3, wherein the bit slicer comprises a bit-slicing voltage comparator having an input terminal for receiving the analog signal and an input terminal for receiving the fast-settling threshold voltage, wherein an output of the bit-slicing voltage comparator comprises the binary signal.

5. The fast-settling threshold estimator of claim 1, wherein the maximum peak detector includes a transconductance amplifier having a first input terminal for receiving the analog signal, and a second input terminal coupled to the output terminal of the maximum peak detector, a terminal coupled to VDD, and a terminal coupled to VSS, wherein the transconductance amplifier produces an output current; a current mirror having an input transistor coupled to the output terminal of the transconductance amplifier, and an output transistor, wherein the current mirror rectifies and amplifies the output current of the transconductance amplifier; a slow decay current source coupled between the output transistor and VSS; and an integrator having an input terminal coupled to the output transistor, a terminal coupled to VDD, a terminal coupled to VSS, and an output terminal, wherein the integrator outputs the estimate of the maximum voltage of the analog signal.

6. The fast-settling threshold estimator of claim 5, wherein the transconductance amplifier is configured to produce the output current proportional to a difference between a voltage of the analog signal and a voltage of the output terminal of the maximum peak detector.

7. The fast-settling threshold estimator of claim 1, wherein the minimum peak detector includes a transconductance amplifier having a first terminal for receiving the analog signal, a second terminal coupled to an output terminal of the minimum peak detector, a third terminal coupled to VDD, a fourth terminal, a fifth terminal, and a sixth terminal coupled to VSS, wherein the transconductance amplifier produces a first output current and a second output current; a first current mirror, coupled to VDD, having an input transistor and an output transistor; a switch coupled between the fourth terminal of the transconductance amplifier and the input transistor of the first current mirror, the switch controlled by the pulse, wherein the first current mirror rectifies and amplifies the first output current depending on a state of the switch; a second current mirror having an input transistor coupled between the fifth terminal and VSS, and having an output transistor, wherein the second current mirror rectifies and amplifies the second output current of the transconductance amplifier; an integrator having an input terminal coupled to the output transistor of the first current mirror and to the output terminal of the second current mirror, a terminal coupled to VDD, a terminal coupled to VSS, and an output terminal; and a slow-decay current source coupled between VDD and the input terminal of the integrator, wherein the integrator outputs the estimate of the minimum voltage of the analog signal.

8. The fast-settling threshold estimator of claim 7, wherein the transconductance amplifier is configured to output the first output current proportional to a difference between a voltage of the output terminal of the minimum peak detector and a voltage of the analog signal, and to output the second output current proportional to a difference between a voltage of the output terminal of the minimum peak detector and a voltage of the analog signal.

9. The fast-settling threshold estimator of claim 1, wherein the output voltage of the differentiator is KdVMAX/dt, where K is a gain factor, VMAX is the estimate of the maximum value of the analog signal, and t is time.

10. An electronic circuit for determining a slicing level of digital data in an analog signal, comprising: a bit-slicing voltage comparator having a positive input terminal for receiving an analog signal containing digital data, a negative input terminal, and an output terminal for outputting a binary signal based on the digital data; a fast-settling threshold estimator for producing a fast-settling threshold voltage, the fast-settling threshold estimator having an input terminal for receiving the analog signal and an output terminal coupled to the negative input terminal of the bit-slicing voltage comparator, wherein the fast-settling threshold estimator includes: a maximum peak detector having an input terminal for receiving the analog signal and having an output terminal, wherein the maximum peak detector produces at its output terminal an estimate of a maximum value of the analog signal, a differentiator having an input terminal coupled to the output terminal of the maximum peak detector, and having an output terminal, wherein the differentiator produces an output signal responsive to a change in the analog signal, a second comparator having a first input terminal coupled to the differentiator and a second input terminal coupled to a constant voltage source having a preselected voltage and having an output terminal, wherein the second comparator outputs a pulse when a voltage of the output signal of the differentiator is greater than the preselected voltage, and a minimum peak detector having a first input terminal for receiving the analog signal and a reset input terminal for receiving the pulse, wherein the pulse resets the minimum peak detector and, after being reset, the minimum peak detector outputs at an output terminal an estimate of a minimum value of the analog signal; and an averaging circuit coupled to the maximum peak detector and to the minimum peak detector for producing a weighted average of the estimate of a maximum value of the analog signal and the estimate of a minimum value of the analog signal, wherein the weighted average is a fast-settling threshold voltage of a slicing level of the digital data.

11. The electronic circuit of claim 10, wherein the maximum peak detector includes a transconductance amplifier having a terminal for receiving the analog signal, a terminal coupled to the output terminal of the maximum peak detector, a terminal coupled to VDD and a terminal coupled to VSS, wherein the transconductance amplifier is configured to output a current proportional to a difference between a voltage of the analog signal and a voltage of the output terminal of the maximum peak detector; a current mirror having an input transistor coupled to the output terminal of the transconductance amplifier, and an output transistor, wherein the current mirror rectifies and amplifies the current of the transconductance amplifier; a slow decay current source coupled between the output transistor and VSS; and an integrator having an input terminal coupled to the output transistor, a terminal coupled to VSS, and an output terminal, wherein integrator outputs the estimate of a maximum voltage of the analog signal.

12. The electronic circuit of claim 11, wherein the integrator includes a capacitor coupled between the input terminal and VSS; and an operational amplifier having a positive input coupled to the input terminal of the integrator, an output coupled to the output terminal of the integrator, and a negative input, wherein the output of the operational amplifier is coupled to the negative input of the operational amplifier in an active follower configuration.

13. The electronic circuit of claim 11 wherein, when the voltage of the output terminal of the maximum peak detector is less than the voltage of the analog signal, the current mirror outputs a fast-attack current proportional to the output current of the transconductance amplifier.

14. The electronic circuit of claim 10, wherein the minimum peak detector includes a transconductance amplifier having a negative input terminal for receiving the analog signal, a positive input terminal coupled to an output terminal of the minimum peak detector, a terminal coupled to VDD, a terminal coupled to VSS, and an output terminal, wherein the transconductance amplifier is configured to output an output current proportional to a difference between a voltage at the output terminal and the voltage of the analog signal; a current mirror for rectifying and amplifying the output current of the transconductance amplifier, the current mirror having an input transistor and an output transistor, wherein a drain electrode of the input transistor is coupled to the output terminal of the transconductance amplifier and a source electrode of the input transistor is coupled to VSS; a switch coupled between the VDD and a drain electrode of the output transistor, the switch controlled by the pulse, wherein the source electrode of the output transistor is coupled to VSS; an integrator having an input terminal coupled to the drain electrode of the output transistor, a terminal coupled to VDD, a terminal coupled to VSS, and an output terminal coupled to the output terminal of the minimum peak detector; and a slow-decay current source coupled between the VDD and the input terminal of the integrator, wherein, when the switch is conducting, a fast-reset current is sourced to the input terminal of the integrator, and wherein the integrator outputs the estimate of a minimum voltage of the analog signal.

15. The electronic circuit of claim 14, wherein the minimum peak detector produces the fast-reset current to the input terminal of the integrator based on an expression {RESET*(VDD−VOUT)/RON}, where RON is an on-resistance of the switch, where RESET=(1 or 0), and where RESET is set by the pulse.

16. A radio frequency (RF) receiver, comprising: an RF low-noise amplifier coupled to an antenna for receiving digital data in an RF analog signal; an RF-envelope detector coupled to the RF low-noise amplifier for downmixing the RF analog signal and for outputting a baseband analog signal; a semi-logarithmic baseband transimpedance amplifier coupled to the RF-envelope detector; a baseband low-pass filter having an input coupled to the semi-logarithmic baseband transimpedance amplifier and having an output terminal; a fast-settling threshold estimator having an input terminal coupled to the output terminal of the baseband low-pass filter and having an output terminal for outputting a fast-settling threshold voltage; and a bit slicer having a first input terminal coupled to the output terminal of the baseband low-pass filter and a second input terminal coupled to the output terminal of the fast-settling threshold estimator, wherein the bit slicer outputs a binary signal responsive to the digital data in the analog RF signal and responsive to the fast-settling threshold voltage.

17. The radio frequency receiver of claim 16, wherein the bit slicer includes a bit-slicing voltage comparator having a first input for receiving the baseband analog signal and a second input coupled to the output terminal of the fast-settling threshold estimator, wherein an output of the bit-slicing voltage comparator comprises the binary signal.

18. The radio frequency receiver of claim 16, wherein the fast-settling threshold estimator includes a maximum peak detector for receiving an analog signal, wherein the maximum peak detector produces an estimate of a maximum value of the analog signal at its output terminal; a differentiator having an input terminal coupled to the maximum peak detector, wherein the differentiator produces at its output terminal an output voltage responsive to a change in the maximum value of the analog signal; a comparator having a first input terminal coupled to the differentiator and a second input terminal coupled to a constant voltage source and having an output terminal, wherein the comparator outputs a pulse when the output voltage of the differentiator is greater than a voltage of the constant voltage source; a minimum peak detector having a first input terminal for receiving the analog signal and a reset input terminal for receiving the pulse, wherein the pulse resets the minimum peak detector and, after being reset, the minimum peak detector produces an estimate of a minimum value of the analog signal at its output terminal; a first resistor having one end coupled to the output terminal of the maximum peak detector and another end coupled to a node; and a second resistor having one end coupled to the output terminal of the minimum peak detector and another end coupled to the node, wherein a voltage at the node is a fast-settling threshold voltage.

19. The radio frequency receiver of claim 18, wherein the maximum peak detector includes a transconductance amplifier having a first input terminal for receiving the analog signal, and a second input terminal coupled to the output terminal of the maximum peak detector, a terminal coupled to VDD and a terminal coupled to VSS, wherein the transconductance amplifier is configured to produce an output current proportional to a difference between a voltage of the analog signal and a voltage of the output terminal of the maximum peak detector; a current mirror, coupled to VDD, having an input transistor coupled to the output terminal of the transconductance amplifier, and an output transistor, wherein the current mirror rectifies and amplifies the output current of the transconductance amplifier; a slow decay current source coupled between the output transistor and VSS; and an integrator having an input terminal coupled to the output transistor, a terminal coupled to VDD, a terminal coupled to VSS, and an output terminal, wherein integrator outputs the estimate of a maximum voltage of the analog signal.

20. The radio frequency receiver of claim 18, wherein the minimum peak detector includes a transconductance amplifier having a negative input terminal for receiving the analog signal, a positive input terminal coupled to an output terminal of the minimum peak detector, a third terminal coupled to VDD, a fourth terminal, a fifth terminal coupled to a second current mirror, and a sixth terminal coupled to VSS, wherein the transconductance amplifier is configured to output two currents proportional to a difference between a voltage of the output terminal of the minimum peak detector and a voltage of the analog signal; a first current mirror having an input transistor and an output transistor; a switch coupled between the fourth terminal of the transconductance amplifier and the input transistor of the first current mirror, the switch controlled by the pulse, wherein the first current mirror rectifies and amplifies a first output current depending on a state of the switch; a second current mirror having an input transistor coupled between the fifth terminal and VSS, and having an output transistor, wherein the second current mirror rectifies and amplifies a second output current of the transconductance amplifier; an integrator having an input terminal coupled to the output transistor of the first current mirror and to the output terminal of the second current mirror, a terminal coupled to VDD, a terminal coupled to VSS, and an output terminal; and a slow-decay current source coupled between VDD and the input terminal of the integrator, wherein the integrator outputs the estimate of a minimum voltage of the analog signal.

The term “coupled”, as used herein, is defined as “connected”, and encompasses the coupling of devices that may be physically, electrically or communicatively connected, although the coupling may not necessarily be directly, and not necessarily be mechanically. The term “configured to” describes hardware, software or a combination of hardware and software that is adapted to, set up, arranged, built, composed, constructed, designed or that has any combination of these characteristics to carry out a given function.

The terms “a” or “an”, as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an”. The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements.

The Detailed Description section, and not the Abstract section, is intended to be used to interpret the claims. The Abstract section may set forth one or more but not all embodiments of the invention, and the Abstract section is not intended to limit the invention or the claims in any way.

Although the invention is described herein with reference to specific embodiments, various modifications and changes can be made without departing from the scope of the present invention as set forth in the claims below. Accordingly, the specification and figures are to be regarded in an illustrative rather than a restrictive sense, and all such modifications are intended to be included within the scope of the present invention. Any benefits, advantages or solutions to problems that are described herein with regard to specific embodiments are not intended to be construed as a critical, required, or essential feature or element of any or all the claims.

1. A fast-settling threshold estimator for determining a fast-settling threshold voltage, comprising:
a maximum peak detector for receiving an analog signal, the analog signal containing digital data, wherein the maximum peak detector produces at its output terminal an estimate of a maximum value of the analog signal within a predetermined time range;
a differentiator coupled to the maximum peak detector, wherein the differentiator produces an output voltage having a value responsive to a change in the estimate of the maximum value of the analog signal;
a constant voltage source having a preselected voltage;
a comparator having a first input terminal coupled to the differentiator and a second input terminal coupled to the constant voltage source, wherein the comparator outputs a pulse when the output voltage of the differentiator is greater than the preselected voltage;
a minimum peak detector having a first input terminal for receiving the analog signal and a reset input terminal for receiving the pulse, wherein the pulse resets the minimum peak detector and, after being reset, the minimum peak detector produces at its output terminal an estimate of a minimum value of the analog signal within a predetermined time range; and
an averaging circuit coupled to the maximum peak detector and to the minimum peak detector for producing a weighted average of the estimate of the maximum value of the analog signal and the estimate of the minimum value of the analog signal, wherein the weighted average is a fast-settling threshold voltage.

2. The fast-settling threshold estimator of claim 1, wherein the differentiator outputs a voltage that is linear with a rate of change in the analog signal.

3. The fast-settling threshold estimator of claim 2, including a bit slicer wherein, based in part on the fast-settling threshold voltage, the bit slicer outputs a binary signal corresponding to the digital data.

4. The fast-settling threshold estimator of claim 3, wherein the bit slicer comprises a bit-slicing voltage comparator having an input terminal for receiving the analog signal and an input terminal for receiving the fast-settling threshold voltage, wherein an output of the bit-slicing voltage comparator comprises the binary signal.

5. The fast-settling threshold estimator of claim 1, wherein the maximum peak detector includes
a transconductance amplifier having a first input terminal for receiving the analog signal, and a second input terminal coupled to the output terminal of the maximum peak detector, a terminal coupled to V_{DD}, and a terminal coupled to V_{SS}, wherein the transconductance amplifier produces an output current;
a current mirror having an input transistor coupled to the output terminal of the transconductance amplifier, and an output transistor, wherein the current mirror rectifies and amplifies the output current of the transconductance amplifier;
a slow decay current source coupled between the output transistor and V_{SS}; and
an integrator having an input terminal coupled to the output transistor, a terminal coupled to V_{DD}, a terminal coupled to V_{SS}, and an output terminal, wherein the integrator outputs the estimate of the maximum voltage of the analog signal.

6. The fast-settling threshold estimator of claim 5, wherein the transconductance amplifier is configured to produce the output current proportional to a difference between a voltage of the analog signal and a voltage of the output terminal of the maximum peak detector.

7. The fast-settling threshold estimator of claim 1, wherein the minimum peak detector includes
a transconductance amplifier having a first terminal for receiving the analog signal, a second terminal coupled to an output terminal of the minimum peak detector, a third terminal coupled to V_{DD}, a fourth terminal, a fifth terminal, and a sixth terminal coupled to V_{SS}, wherein the transconductance amplifier produces a first output current and a second output current;
a first current mirror, coupled to V_{DD}, having an input transistor and an output transistor;
a switch coupled between the fourth terminal of the transconductance amplifier and the input transistor of the first current mirror, the switch controlled by the pulse, wherein the first current mirror rectifies and amplifies the first output current depending on a state of the switch;
a second current mirror having an input transistor coupled between the fifth terminal and V_{SS}, and having an output transistor, wherein the second current mirror rectifies and amplifies the second output current of the transconductance amplifier;
an integrator having an input terminal coupled to the output transistor of the first current mirror and to the output terminal of the second current mirror, a terminal coupled to V_{DD}, a terminal coupled to V_{SS}, and an output terminal; and
a slow-decay current source coupled between V_{DD} and the input terminal of the integrator,
wherein the integrator outputs the estimate of the minimum voltage of the analog signal.

8. The fast-settling threshold estimator of claim 7, wherein the transconductance amplifier is configured to output the first output current proportional to a difference between a voltage of the output terminal of the minimum peak detector and a voltage of the analog signal, and to output the second output current proportional to a difference between a voltage of the output terminal of the minimum peak detector and a voltage of the analog signal.

9. The fast-settling threshold estimator of claim 1, wherein the output voltage of the differentiator is KdV_{MAX}/dt, where K is a gain factor, V_{MAX} is the estimate of the maximum value of the analog signal, and t is time.

10. An electronic circuit for determining a slicing level of digital data in an analog signal, comprising:
a bit-slicing voltage comparator having a positive input terminal for receiving an analog signal containing digital data, a negative input terminal, and an output terminal for outputting a binary signal based on the digital data;
a fast-settling threshold estimator for producing a fast-settling threshold voltage, the fast-settling threshold estimator having an input terminal for receiving the analog signal and an output terminal coupled to the negative input terminal of the bit-slicing voltage comparator, wherein the fast-settling threshold estimator includes:
a maximum peak detector having an input terminal for receiving the analog signal and having an output terminal, wherein the maximum peak detector produces at its output terminal an estimate of a maximum value of the analog signal,
a differentiator having an input terminal coupled to the output terminal of the maximum peak detector, and having an output terminal, wherein the differentiator produces an output signal responsive to a change in the analog signal,
a second comparator having a first input terminal coupled to the differentiator and a second input terminal coupled to a constant voltage source having a preselected voltage and having an output terminal, wherein the second comparator outputs a pulse when a voltage of the output signal of the differentiator is greater than the preselected voltage, and
a minimum peak detector having a first input terminal for receiving the analog signal and a reset input terminal for receiving the pulse, wherein the pulse resets the minimum peak detector and, after being reset, the minimum peak detector outputs at an output terminal an estimate of a minimum value of the analog signal; and
an averaging circuit coupled to the maximum peak detector and to the minimum peak detector for producing a weighted average of the estimate of a maximum value of the analog signal and the estimate of a minimum value of the analog signal, wherein the weighted average is a fast-settling threshold voltage of a slicing level of the digital data.

11. The electronic circuit of claim 10, wherein the maximum peak detector includes
a transconductance amplifier having a terminal for receiving the analog signal, a terminal coupled to the output terminal of the maximum peak detector, a terminal coupled to V_{DD} and a terminal coupled to V_{SS}, wherein the transconductance amplifier is configured to output a current proportional to a difference between a voltage of the analog signal and a voltage of the output terminal of the maximum peak detector;
a current mirror having an input transistor coupled to the output terminal of the transconductance amplifier, and an output transistor, wherein the current mirror rectifies and amplifies the current of the transconductance amplifier;
a slow decay current source coupled between the output transistor and V_{SS}; and
an integrator having an input terminal coupled to the output transistor, a terminal coupled to V_{SS}, and an output terminal, wherein integrator outputs the estimate of a maximum voltage of the analog signal.

12. The electronic circuit of claim 11, wherein the integrator includes
a capacitor coupled between the input terminal and V_{SS}; and
an operational amplifier having a positive input coupled to the input terminal of the integrator, an output coupled to the output terminal of the integrator, and a negative input, wherein the output of the operational amplifier is coupled to the negative input of the operational amplifier in an active follower configuration.

13. The electronic circuit of claim 11 wherein, when the voltage of the output terminal of the maximum peak detector is less than the voltage of the analog signal, the current mirror outputs a fast-attack current proportional to the output current of the transconductance amplifier.

14. The electronic circuit of claim 10, wherein the minimum peak detector includes
a transconductance amplifier having a negative input terminal for receiving the analog signal, a positive input terminal coupled to an output terminal of the minimum peak detector, a terminal coupled to V_{DD}, a terminal coupled to V_{SS}, and an output terminal, wherein the transconductance amplifier is configured to output an output current proportional to a difference between a voltage at the output terminal and the voltage of the analog signal;
a current mirror for rectifying and amplifying the output current of the transconductance amplifier, the current mirror having an input transistor and an output transistor, wherein a drain electrode of the input transistor is coupled to the output terminal of the transconductance amplifier and a source electrode of the input transistor is coupled to V_{SS};
a switch coupled between the V_{DD} and a drain electrode of the output transistor, the switch controlled by the pulse, wherein the source electrode of the output transistor is coupled to V_{SS};
an integrator having an input terminal coupled to the drain electrode of the output transistor, a terminal coupled to V_{DD}, a terminal coupled to V_{SS}, and an output terminal coupled to the output terminal of the minimum peak detector; and
a slow-decay current source coupled between the V_{DD} and the input terminal of the integrator,
wherein, when the switch is conducting, a fast-reset current is sourced to the input terminal of the integrator, and
wherein the integrator outputs the estimate of a minimum voltage of the analog signal.

15. The electronic circuit of claim 14, wherein the minimum peak detector produces the fast-reset current to the input terminal of the integrator based on an expression {RESET*(V_{DD}−V_{OUT})/R_{ON}}, where R_{ON} is an on-resistance of the switch, where RESET=(1 or 0), and where RESET is set by the pulse.

16. A radio frequency (RF) receiver, comprising:
an RF low-noise amplifier coupled to an antenna for receiving digital data in an RF analog signal;
an RF-envelope detector coupled to the RF low-noise amplifier for downmixing the RF analog signal and for outputting a baseband analog signal;
a semi-logarithmic baseband transimpedance amplifier coupled to the RF-envelope detector;
a baseband low-pass filter having an input coupled to the semi-logarithmic baseband transimpedance amplifier and having an output terminal;
a fast-settling threshold estimator having an input terminal coupled to the output terminal of the baseband low-pass filter and having an output terminal for outputting a fast-settling threshold voltage; and
a bit slicer having a first input terminal coupled to the output terminal of the baseband low-pass filter and a second input terminal coupled to the output terminal of the fast-settling threshold estimator, wherein the bit slicer outputs a binary signal responsive to the digital data in the analog RF signal and responsive to the fast-settling threshold voltage.

17. The radio frequency receiver of claim 16, wherein the bit slicer includes a bit-slicing voltage comparator having a first input for receiving the baseband analog signal and a second input coupled to the output terminal of the fast-settling threshold estimator, wherein an output of the bit-slicing voltage comparator comprises the binary signal.

18. The radio frequency receiver of claim 16, wherein the fast-settling threshold estimator includes
a maximum peak detector for receiving an analog signal, wherein the maximum peak detector produces an estimate of a maximum value of the analog signal at its output terminal;
a differentiator having an input terminal coupled to the maximum peak detector, wherein the differentiator produces at its output terminal an output voltage responsive to a change in the maximum value of the analog signal;
a comparator having a first input terminal coupled to the differentiator and a second input terminal coupled to a constant voltage source and having an output terminal, wherein the comparator outputs a pulse when the output voltage of the differentiator is greater than a voltage of the constant voltage source;
a minimum peak detector having a first input terminal for receiving the analog signal and a reset input terminal for receiving the pulse, wherein the pulse resets the minimum peak detector and, after being reset, the minimum peak detector produces an estimate of a minimum value of the analog signal at its output terminal;
a first resistor having one end coupled to the output terminal of the maximum peak detector and another end coupled to a node; and
a second resistor having one end coupled to the output terminal of the minimum peak detector and another end coupled to the node,
wherein a voltage at the node is a fast-settling threshold voltage.

19. The radio frequency receiver of claim 18, wherein the maximum peak detector includes
a transconductance amplifier having a first input terminal for receiving the analog signal, and a second input terminal coupled to the output terminal of the maximum peak detector, a terminal coupled to V_{DD} and a terminal coupled to V_{SS}, wherein the transconductance amplifier is configured to produce an output current proportional to a difference between a voltage of the analog signal and a voltage of the output terminal of the maximum peak detector;
a current mirror, coupled to V_{DD}, having an input transistor coupled to the output terminal of the transconductance amplifier, and an output transistor, wherein the current mirror rectifies and amplifies the output current of the transconductance amplifier;
a slow decay current source coupled between the output transistor and V_{SS}; and
an integrator having an input terminal coupled to the output transistor, a terminal coupled to V_{DD}, a terminal coupled to V_{SS}, and an output terminal, wherein integrator outputs the estimate of a maximum voltage of the analog signal.

20. The radio frequency receiver of claim 18, wherein the minimum peak detector includes
a transconductance amplifier having a negative input terminal for receiving the analog signal, a positive input terminal coupled to an output terminal of the minimum peak detector, a third terminal coupled to V_{DD}, a fourth terminal, a fifth terminal coupled to a second current mirror, and a sixth terminal coupled to V_{SS}, wherein the transconductance amplifier is configured to output two currents proportional to a difference between a voltage of the output terminal of the minimum peak detector and a voltage of the analog signal;
a first current mirror having an input transistor and an output transistor;
a switch coupled between the fourth terminal of the transconductance amplifier and the input transistor of the first current mirror, the switch controlled by the pulse, wherein the first current mirror rectifies and amplifies a first output current depending on a state of the switch;
a second current mirror having an input transistor coupled between the fifth terminal and V_{SS}, and having an output transistor, wherein the second current mirror rectifies and amplifies a second output current of the transconductance amplifier;
an integrator having an input terminal coupled to the output transistor of the first current mirror and to the output terminal of the second current mirror, a terminal coupled to V_{DD}, a terminal coupled to V_{SS}, and an output terminal; and
a slow-decay current source coupled between V_{DD} and the input terminal of the integrator, wherein the integrator outputs the estimate of a minimum voltage of the analog signal.
